(19) United States
(12) Patent Application Publication
(10) Pub. No.: US 2024/0006225 A1
(43) Pub. Date: Jan. 4, 2024

(54) SUSCEPTOR FOR EPITAXIAL PROCESSING AND EPITAXIAL REACTOR INCLUDING THE SUSCEPTOR

(71) Applicant: GlobalWafers Co., Ltd., Hsinchu (TW)

(72) Inventors: Manabu Hamano, Utsunomiya City (JP); Chun-Chin Tu, Zhubei City (TW)

(21) Appl. No.: 18/327,546

(22) Filed: Jun. 1, 2023

Related U.S. Application Data
(60) Provisional application No. 63/367,400, filed on Jun. 30, 2022.

(51) Int. Cl. H01L 21/687; C30B 25/12

(52) U.S. Cl. CPC H01L 21/68735; C30B 25/12

(57) ABSTRACT

A susceptor for supporting a semiconductor wafer in a heated chamber includes a body that has a front surface, a rear surface, and a central plane between the front and rear surfaces. The susceptor also includes a recess that extends into the body from the front surface to a recess floor and a ledge that circumscribes the recess floor in the recess. The ledge includes a first surface oriented at a first angle relative to a horizontal plane parallel to the central plane, a second surface that extends radially inward from the first surface, the second surface optionally oriented at a second acute angle relative to the horizontal plane, and a third surface that extends between the second surface and the recess floor, the third surface oriented at a third acute angle relative to the horizontal plane. Each of the first, second, and third surfaces extends circumferentially along the ledge.

### CROSS-REFERENCE TO RELATED APPLICATION

This application claims priority to U.S. Provisional Patent Application No. 63/367,400, filed Jun. 30, 2022, the disclosure of which is hereby incorporated herein by reference in its entirety.

### FIELD

The field of the disclosure generally relates to semiconductor wafer processing, and more particularly to susceptors for epitaxial processing.

### BACKGROUND

Epitaxial chemical vapor deposition is a process for growing a thin layer of material on a semiconductor wafer so that the lattice structure is identical to that of the wafer. Using this process, a layer having different conductivity type, dopant species, or dopant concentration may be applied to the semiconductor wafer to achieve the necessary electrical properties.

Prior to epitaxial deposition (or “epitaxy”), the semiconductor wafer is typically mounted on a susceptor in a deposition chamber of a reactor. The epitaxial deposition process begins by introducing a cleaning gas to a front surface of the wafer to pre-heat and clean the front surface of the wafer. The cleaning gas removes native oxide from the front surface, permitting the epitaxial silicon layer to grow continuously and evenly on the surface during a subsequent step of the deposition process. The epitaxial deposition process continues by introducing a vaporous silicon source gas to the front surface of the wafer to deposit and grow an epitaxial layer of silicon on the front surface. A back surface opposite the front surface of the susceptor may be simultaneously subjected to hydrogen gas. The susceptor, which supports the semiconductor wafer in the deposition chamber during the epitaxial deposition, is rotated during the process to ensure the epitaxial layer grows evenly.

A common susceptor design includes a disk-shaped body having a recess with a concave or sloped ledge. The recess is defined in a top surface of the disk-shaped body of the susceptor by a sidewall that extends downward from a peripheral rim of the top surface. The diameter of the recess is generally greater than the diameter of the wafer such that the sidewall is spaced a distance from the peripheral edge of the wafer. The sloped ledge supports the back surface of the wafer near the peripheral edge and the sloped ledge extends between the sidewall and the floor of the recess. The ledge may be sized and shaped so that the back surface of the wafer only contacts the susceptor very near the peripheral edge of the wafer, and the recess floor is spaced from the back surface of the wafer. As such, damage to the polished back surface is reduced. With increasing angle of slope of the ledge, the damage to the polished back surface may be further reduced.

Back surface deposition is generally an undesirable effect of epitaxial deposition in that it causes variations in epitaxial delta edge roll-off (DERO) of the wafer, and these variations may ultimately negatively affect flatness of the wafer. DERO is defined as the change in the thickness profile of the peripheral edge of the wafer, i.e. “edge roll-off” or ERO, before and after epitaxy. Epitaxial deposition processes tend to deposit a small amount of silicon on the back surface of the wafer. This back surface deposition may be due to the silicon source gas that flows across the front surface of the wafer leaking between a peripheral edge of the wafer and the susceptor at the ledge. The leaking source gas leads to excessive growth on the back surface of the wafer, which may thicken the near-edge region of the wafer (within a few millimeters, e.g., within 5-6 mm, within 3-4 mm or within 1-2 mm of the peripheral edge of the wafer) relative to regions that are inward of the edge. Such thickening may increase DERO. Further, the thickening effect of back surface deposition may be non-uniform along the near-edge region of the wafer, and the DERO varies circumferentially along the wafer as a result. Variations in the DERO may cause a mis-match between the ERO profile post-epitaxy and the ERO profile before epitaxy along the near-edge region of the wafer, and this mis-match negatively affects the flatness of the wafer. Flatness of the wafer may be measured by flatness parameters such as, for example, site backside ideal plane/range (SBIR), global backside ideal plane/range (GBIR), site frontside least squares focal plane range (SFQR), and edge site frontside least squares focal plane range (ESFQR).

In conventional susceptor designs, variations in the DERO may be consequence of variations in the flatness or thickness of the susceptor along the circumferential extent of the ledge (also referred to as the “ledge flatness”). In particular, the ledge flatness may vary circumferentially along the portion of the ledge that contacts the back surface of the wafer. The variations in ledge flatness may lead to deviations in the deposition rate of silicon source gas near the edge of the silicon wafer, which lead to the DERO variations. For example, the amount of silicon source gas that leaks between the wafer and the ledge may be non-uniform about the circumference of the wafer as a result of ledge flatness variations. The variations in the ledge flatness may be caused by manufacturing tolerances and can only be controlled to a certain extent. Moreover, Applicant has discovered that the slope of the ledge in conventional susceptor designs, in which the ledge is sloped at a single angle substantially along the circumference of the ledge, is insufficient to control the DERO variations caused by ledge flatness variations.

Accordingly, a need exists for a susceptor with a ledge design that facilitates minimizing or eliminating the impact that ledge flatness variations have on wafer flatness during an epitaxial deposition process.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

In one aspect, a susceptor supports a semiconductor wafer in a heated chamber, and the susceptor includes a body that has a front surface, a rear surface opposite the front surface, and a central plane extending between the front and rear surfaces. The susceptor also includes a recess that extends into the body from the front surface to a recess floor. The recess receives the semiconductor wafer. The semiconductor wafer includes a forward surface, a back surface, and a peripheral edge joining the front and back surfaces. The susceptor also includes a ledge that circumscribes an outer periphery of the recess floor in the recess. The ledge supports the back surface of the semiconductor wafer proximate the peripheral edge. The ledge includes a first surface oriented at a first acute angle relative to a horizontal plane parallel to the central plane, a second surface that extends radially inward from the first surface, the second surface optionally oriented at a second acute angle relative to the horizontal plane, and a third surface that extends between the second surface and the recess floor, the third surface oriented at a third acute angle relative to the horizontal plane. Each of the first, second, and third surfaces extends circumferentially along the ledge.

In another aspect, a susceptor for supporting a semiconductor wafer in a heated chamber includes a body that has a front surface, a rear surface opposite the front surface, and a central plane extending between the front and rear surfaces. The susceptor also includes a wall that extends from the front surface and defines a recess in the body. The recess is sized and shaped for receiving the semiconductor wafer therein. The susceptor also includes a ledge that extends between the wall and a recess floor. The ledge includes a first surface oriented at a first acute angle relative to a horizontal plane parallel to the central plane, a second surface oriented at a second angle relative to the horizontal plane that is smaller than the first angle, and a third surface oriented at a third acute angle relative to the horizontal plane. Each of the first, second, and third surfaces extends circumferentially along the ledge, and the second surface is positioned between the first surface and the third surface.

In another aspect, an epitaxial deposition reactor for growing a thin layer of material on a semiconductor wafer includes a reaction chamber and a susceptor to support the semiconductor wafer within the reaction chamber. The susceptor includes a body that has a front surface, a rear surface opposite the front surface, and a central plane extending between the front and rear surfaces. The susceptor also includes a recess that extends into the body from the front surface to a recess floor. The recess is sized and shaped for receiving the semiconductor wafer therein. The susceptor also includes a ledge that circumscribes an outer periphery of the recess floor in the recess. The ledge includes a first surface oriented at a first acute angle relative to a horizontal plane parallel to the central plane, a second surface that extends radially inward from the first surface, the second surface optionally oriented at a second acute angle relative to the horizontal plane, and a third surface that extends between the second surface and the recess floor, the third surface oriented at a third acute angle relative to the horizontal plane. Each of the first, second, and third surfaces extends circumferentially along the ledge.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a top view of a susceptor for supporting a semiconductor wafer in a heated chamber.

FIG. 2 is a bottom view of the susceptor of FIG. 1.

FIG. 3 is a schematic cross section of the susceptor of FIG. 1 supporting a semiconductor wafer in a heated chamber.

FIG. 4 is a partial cross section of the susceptor of FIG. 1 taken along line 1-1 of FIG. 1.

FIG. 5 is an enlarged view of a portion A of the susceptor shown in FIG. 4.

FIG. 6 is a plot illustrating a ledge flatness profile of a conventional susceptor having a single angle ledge design.

FIG. 7 is a plot illustrating a DERO profile of an epitaxial wafer processed by a conventional susceptor having the ledge flatness profile shown in FIG. 6.

FIG. 8 is a plot illustrating a ledge flatness profile of an example susceptor having a triple angle ledge design according to the present disclosure.

FIG. 9 is a plot illustrating a DERO profile of an epitaxial wafer processed by an example susceptor having the ledge flatness profile shown in FIG. 8.

Corresponding reference characters indicate corresponding parts throughout the several views of the drawings.

### DETAILED DESCRIPTION

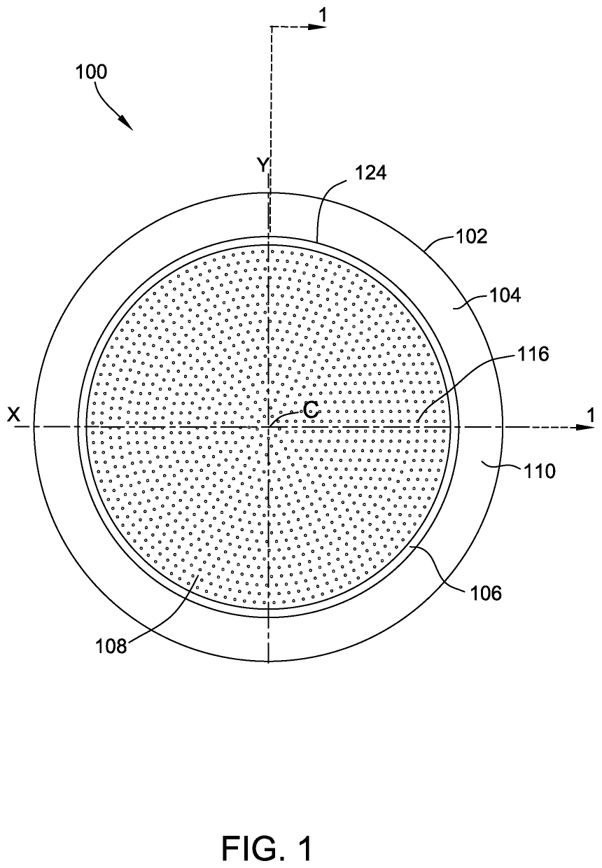

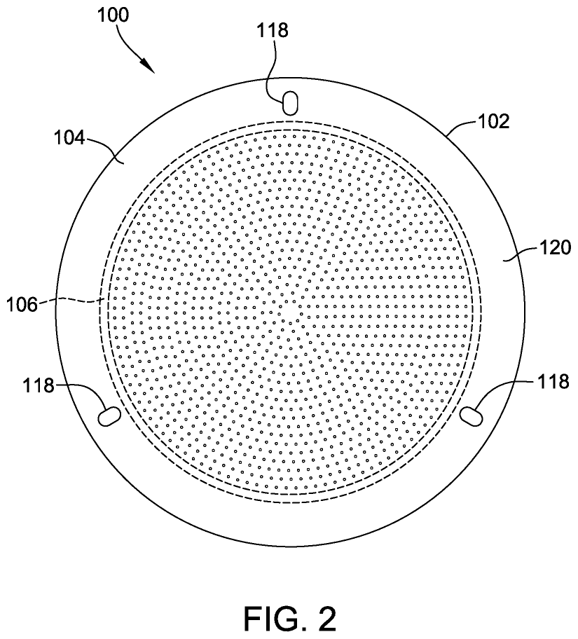

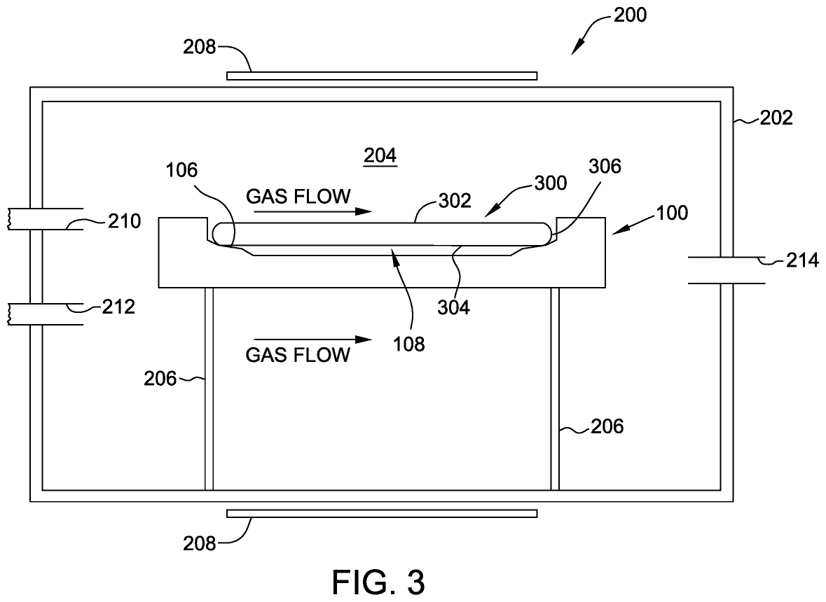

FIG. 1 is a top view of an example susceptor 100. FIG. 2 is a rear view of the susceptor 100. In the example implementation, the susceptor 100 supports a semiconductor wafer (e.g., wafer 300 shown in FIG. 3) in a heated chamber (e.g., in a chemical vapor deposition reactor 200 shown in FIG. 3). Generally, and in embodiments of the present disclosure, suitable semiconductor wafers (which may also be referred to as “wafers” or “silicon wafers”) include single crystal silicon wafers, such as, for example, silicon wafers obtained by slicing the silicon wafers from ingots formed by the Czochralski method or the float zone method. Each semiconductor wafer includes a central axis, a forward or front surface, and a back surface parallel to the front surface. The front and back surfaces are generally perpendicular to the central axis. A circumferential or peripheral edge joins the front and back surfaces. The semiconductor wafers may be any diameter suitable for use by those of skill in the art including, for example, 150 millimeter, 200 millimeter, 300 millimeter, or 450 millimeter diameter wafers.

The susceptor 100 includes a generally disk-shaped body 102. The body 102 includes an outer rim 104, a ledge 106, and a recess 108 formed in a front surface 110 of the body 102. The recess 108 is sized and shaped for receiving the semiconductor wafer during processing and the ledge 106 supports the semiconductor wafer positioned in the recess 108. Although the susceptor 100 may have other overall dimensions without departing from the scope of the present disclosure, in one embodiment the susceptor 100 can be sized and configured such that the ledge 106 of the susceptor 100 can accommodate any diameter semiconductor wafer including, for example, 150 millimeter, 200 millimeter, 300 millimeter, or 450 millimeter diameter wafers.

Further, although the susceptor 100 may be made of other materials, in the embodiment illustrated in FIGS. 1 and 2, the susceptor 100 is constructed of conventional materials such as high purity graphite and has a silicon carbide layer covering the graphite to reduce the amount of contaminants released into the surrounding ambient from the graphite during the high temperature epitaxial deposition process.

The susceptor 100 also includes a plurality of holes 116 extending through the recess 108 of the body 102. It will be recognized by one skilled in the art that the holes 116 could be squares, slots, or any other shapes allowing fluid flow therethrough. The holes 116 are spaced on the susceptor 100 to allow a cleaning gas utilized during the pre-bake step of the epitaxial deposition process to contact and etch substantially the entire back surface of the semiconductor wafer. Holes 116 are spaced sufficiently apart to allow the cleaning gas to contact substantially the entire back surface of the semiconductor wafer such that it may etch substantially all of the native oxide from the back surface. Additionally, in the embodiment illustrated in FIGS. 1 and 2, the holes 116 generally form a plurality of concentric rings, for example, the holes 116 form approximately between 10 and 30 rings.

As shown in FIG. 2, susceptor 100 also includes three equally spaced, race-track-shaped holes 118 that extend into the susceptor 100 from a rear surface 120 for receiving the upper ends of conventional rotatable supports 206 (shown in FIG. 3). These holes 118 engage the supports 206 to prevent the susceptor 100 from slipping on the supports as they turn during processing.

The susceptor 100 described above may be used as part of a reactor for chemical vapor deposition processes such as an epitaxial deposition process. Referring now to FIG. 3, a reactor for chemical vapor deposition processes is generally designated by 200. The reactor 200 includes an epitaxial reaction chamber 202 having an interior volume or space 204. The susceptor 100 described above is sized and shaped to be positioned within the interior space 204 of the chamber 202 and the susceptor 100 supports a semiconductor wafer 300 within the interior space 204. The susceptor 100 is shown simplified in FIG. 3, and additional features of the susceptor 100 are not all shown in FIG. 3. The wafer 300 includes a forward or front surface 302, a back surface 304, and a circumferential or peripheral edge 306 joining the front surface 302 and the back surface 304.

The wafer 300 is positioned within the recess 108 of the susceptor and is supported by the ledge 106. More specifically, the ledge 106 supports a portion of the back surface 304 of the wafer 300 proximate the peripheral edge 306. The susceptor 100 is attached to a pair of conventional rotatable supports 206 for rotating the susceptor 100 during the epitaxial process. The reaction chamber 202 also contains a heat source, for example heating lamp arrays 208 located above and below the susceptor 100 for heating the wafer 300 during an epitaxial deposition process. An upper gas inlet 210 and lower gas inlet 212 allow gas to be introduced into the interior space 204 of the chamber 202.

The epitaxial reaction chamber 202 containing the susceptor 100 described above may be used for both the cleaning and the growth steps of an epitaxial deposition process. In an example epitaxial deposition process, an epitaxial silicon layer is grown on the front surface 302 of the semiconductor wafer 300. In this example, the silicon wafer 300 is introduced into the epitaxial deposition chamber 202 at atmospheric pressure and centered on the susceptor 100. A cleaning gas, such as hydrogen or a mixture of hydrogen and hydrogen chloride, is introduced into the chamber 202 through inlet 210 to remove the native oxide layers on the front 302 and back surfaces 304 of the semiconductor wafer 300.

Once the native oxide layers have been removed from both the front and back surfaces 302 and 304 of the semiconductor wafer 300, the cleaning gas is discontinued and the temperature in the reaction chamber 202 is adjusted to between about 600° C. and about 1200° C. A silicon containing source gas such as silane, dichlorosilane, or trichlorosilane, for example, is introduced through inlet 210 above the front surface 302 of the semiconductor wafer 300 at a flow rate of between about 1 liter/minute and about 50 liters/minute for a period of time sufficient to grow an epitaxial silicon layer on the front surface 302 of the semiconductor wafer 300 having a thickness of between about 0.1 and about 200 micrometers. At the same time the silicon containing source gas is introduced into the deposition chamber 202 through inlet 210 above the front surface 302 of the semiconductor wafer 300, a gas such as nitrogen, argon, hydrogen, a mixture thereof or the source gas is introduced through inlet 212 below the back surface 304 of the semiconductor wafer 300 at a flow rate of between about 1 liter/minute and about 80 liters/minute such that the purge gas can contact the back surface 304 of the semiconductor wafer 300 and carry out-diffused dopant atoms from the back surface 304 toward to an exhaust outlet 214. The wafer 300 having been subjected to the epitaxial deposition processing may be referred to herein as an “epitaxial wafer.”

Referring to FIGS. 1 and 2, the ledge 106 of the body 102 defines an outer peripheral portion of the recess 108, extending radially inward from the outer rim 104. As described in further detail herein, the ledge 106 is shaped to facilitate minimizing or eliminating the impact that variations in the flatness or thickness of the ledge 106 have on excessive and/or non-uniform growth of an epitaxial layer on a back surface of the wafer (e.g., the back surface 304 of the wafer 300) during deposition. Excessive growth on the back surface increases epitaxial delta edge roll-off (DERO) of the wafer, and non-uniform growth causes variations in DERO. DERO is defined as the change in the thickness profile of the peripheral edge of the wafer, i.e. “edge roll-off” or ERO, before and after epitaxy. Increases and/or variations in DERO may negatively impact a flatness of the epitaxial wafer. Flatness of the wafer may be measured by flatness parameters such as, for example, site backside ideal plane/range (SBIR), global backside ideal plane/range (GBIR), site frontside least squares focal plane range (SFQR), and edge site frontside least squares focal plane range (ESFQR).

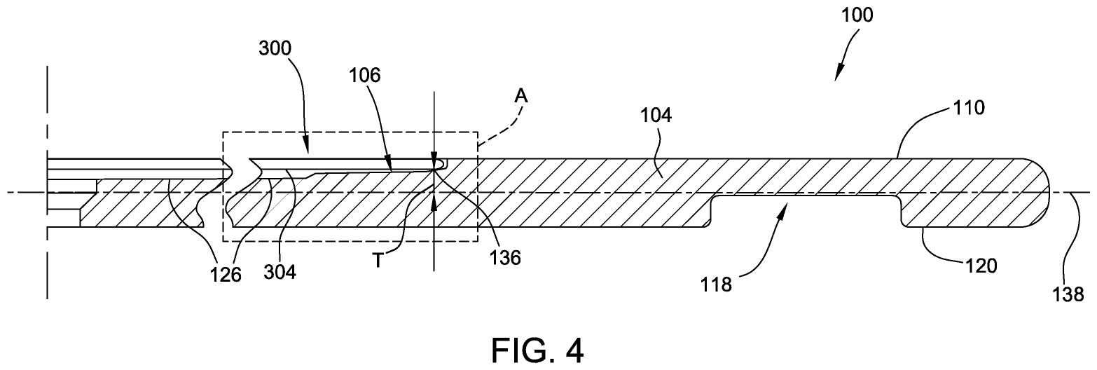

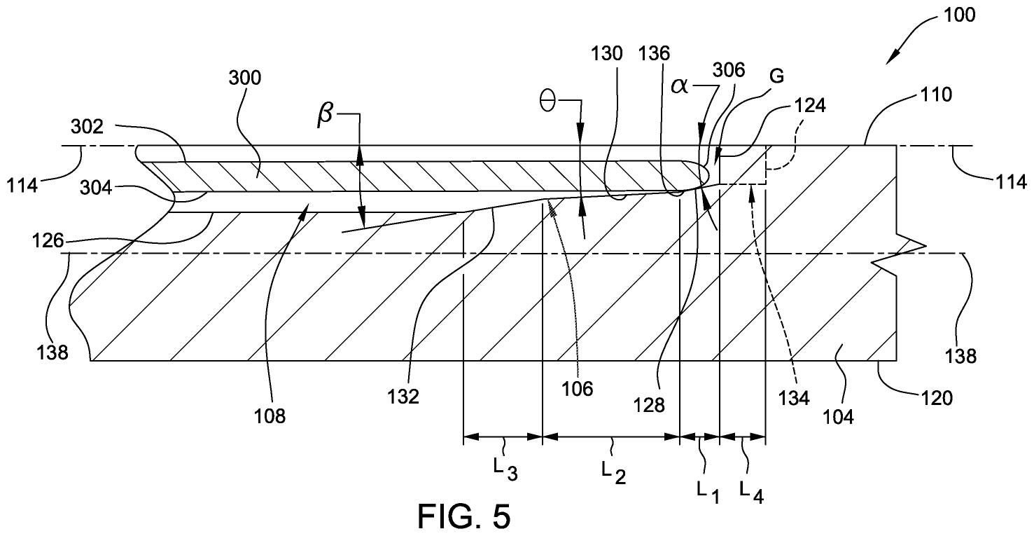

FIG. 4 is a partial cross section of the susceptor 100 of FIG. 1 taken along line 1-1 as shown in FIG. 1, which shows the cross section of the susceptor 100 viewed along a line that overlaps a Y axis above an X axis and intersects with a center C of the recess 108, shown in FIG. 1. FIG. 5 is an enlarged view of a portion A of the susceptor 100 shown in FIG. 4.

Referring to FIGS. 4 and 5, the ledge 106 extends between a recess wall 124 and a recess floor 126, and the ledge 106 circumscribes an outer periphery of the recess floor 126. The recess wall 124 extends between the ledge 106 and the front surface 110 of the outer rim 104. The recess wall 124 may be generally annular and may define a circular shape of the recess 108 (shown in FIG. 1). The recess wall 124 may alternatively have a non-cylindrical shape such that the ledge 106 has a radial length that changes as the ledge 106 extends circumferentially along an outer margin of the recess 108, and the recess 108 may be asymmetrical about at least one of an X axis and a Y axis (shown in FIG. 1). The X axis and the Y axis intersect at the center C of the recess 108.

Suitably, a diameter of the recess 108 is larger than an outer diameter of the wafer 300 so that the wafer 300 is received within the recess 108 without damaging the wafer. As such, when the wafer 300 is positioned within the recess 108, a space G exists between the peripheral edge 306 and the wall 124. The ledge 106 supports a portion of the back surface 304 proximate the peripheral edge 306. In particular, the ledge 106 contacts the back surface 304 at a contact interface 136. As described further below, the ledge 106 generally slopes downward from the wall 124 to the recess floor 126 such that the recess floor 126 is spaced from the back surface 304 of the wafer 300. The recess floor 126 may be curved to account for bowing of the wafer 300 during processing. The plurality of holes 116 (shown in FIGS. 1 and 2) extending through the recess 108 may be formed such that an outer ring of the holes 116 is spaced radially inward from the ledge 106. Alternatively, one or more rings of the holes 116 may be formed on the ledge 106.

The ledge 106 includes a first surface 128, a second surface 130, and a third surface 132. Each of the first surface 128, the second surface 130, and the third surface 132 extends circumferentially along the ledge 106, meaning that the first surface 128, the second surface 130, and the third surface 132 extend along an entire circumferential extent of the ledge 106, or a substantial portion of the circumferential extent of the ledge 106. Reference made herein to a “substantial portion” of the circumferential extent of the ledge 106 means at least (i.e., greater than or equal to) about 60% of the circumferential extent of the ledge 106. For example, the surfaces 128, 130, and 132 may extend along at least 60% of the circumferential extent of the ledge 106. In some examples, the surfaces 128, 130, and 132 may extend along at least about 65%, at least about 70%, at least about 75%, at least about 80%, at least about 85%, at least about 90%, or at least about 95% of the circumferential extent of the ledge 106.

In extending circumferentially along the ledge 106, the surfaces 128, 130, and 132 may extend circumferentially uninterrupted along the entire or a substantial portion of the circumferential extent of the ledge 106. Alternatively, the circumferential extent of the surfaces 128, 130, and 132 may be interrupted at regular or irregular intervals. In examples where the surfaces 128, 130, and 132 are interrupted at regular or irregular intervals in extending circumferentially along the ledge 106, the individual portions of the surfaces 128, 130, and 132 collectively extend circumferentially along at least a substantial portion of the circumferential extent of the ledge 106.

The cross section of the ledge 106 along the entire circumferential extent, or a substantial portion of the circumferential extent, of the ledge 106 includes the first surface 128, the second surface 130, and the third surface 132 as shown in FIG. 5. For example, the cross section of the susceptor 100 shown in FIGS. 4 and 5 is taken along the line that overlaps the Y axis above the X axis (shown in FIG. 1), and a cross section of the susceptor 100 taken along a line that overlaps the Y axis below the X axis would also include the ledge 106 having the cross section shown in FIGS. 4 and 5. Moreover, a cross section of the susceptor 100 taken along a line that overlaps the X axis to the right or to the left of the Y axis (shown in FIG. 1) would include the ledge 106 having the cross section shown in FIGS. 4 and 5.

The second surface 130 extends radially inward from the first surface 128 for a length of L₂. The third surface 132 extends radially inward from the second surface 130 to the recess floor 126 for a length of L₃. The first surface 128 extends radially outward from the second surface 130 for a length of L₁. The first surface 128 may extend radially inward from a lower end of the wall 124. Alternatively, the ledge 106 includes a fourth surface 134 that extends between the lower end of the wall 124 and the first surface 128 for a length of L₄. In examples where the ledge 106 includes the fourth surface 134, the fourth surface 134, like the surfaces 128, 130, and 132, extends along an entire circumferential extent of the ledge 106, or a substantial portion of the circumferential extent of the ledge 106. As described in further detail below, the length of L₄ may vary along the circumferential extent of the ledge 106.

The first surface 128 also slopes downward from the wall 124, or from the fourth surface 134, toward the second surface 130. In the example shown in FIG. 5, the first surface 128 supports a portion of the back surface 304 of the wafer 300 proximate the peripheral edge 306. That is, the contact interface 136 is defined between the first surface 128 of the ledge 106 and the back surface 304 of the wafer 300. As shown, the first surface 128 is oriented at a downward angle α, which results in narrow line of contact between the back surface 302 of the wafer 300 and the surface 128. The angle α is an acute angle measured relative to a plane 114 that contains the X axis and the Y axis shown in FIG. 1. The plane 114 is parallel to a central plane 138 of the susceptor 100. The central plane 138 extends between the front surface 110 and the rear surface 120 of the susceptor 100. For convenience, the plane 114 is referred to as a horizontal plane 114, and the term “horizontal plane” as used herein is not intended to limit the susceptor 100 to any particular orientation. In general, the horizontal plane 114 extends across the front surface 110 of the outer rim 104, and the front surface 110 may be coplanar with the horizontal plane 114.

The angle α is suitably, for example, between approximately 0.5° to approximately 5°, between approximately 0.5° to approximately 4.5°, between approximately 0.5° to approximately 4°, between approximately 0.5° to approximately 3.5°, between approximately 1° to approximately 5°, between approximately 1.5° to approximately 5°, between approximately 2° to approximately 5°, between approximately 2.5° to approximately 5°, between approximately 3° to approximately 5°, between approximately 1° to approximately 4.5°, between approximately 1° to approximately 4°, between approximately 1° to approximately 3.5°, between approximately 1.5° to approximately 4.5°, between approximately 1.5° to approximately 4°, between approximately 1.5° to approximately 3.5°, between approximately 2° to approximately 4.5°, between approximately 2° to approximately 4°, between approximately 2° to approximately 3.5°, between approximately 2.5° to approximately 4.5°, between approximately 2.5° to approximately 4°, between approximately 2.5° to approximately 3.5°, between approximately 3° to approximately 4.5°, between approximately 3° to approximately 4°, or between approximately 3° to approximately 3.5°, measured relative to the horizontal plane 114. In one suitable embodiment, the angle α is approximately 3.18°, measured relative to the horizontal plane 114. In other suitable embodiments, the angle α is any angle that enables the susceptor 100 to function as described herein.

The second surface 130 may also slope downward as the second surface 130 extends from the first surface 128 to the third surface 132, or the second surface 130 extends substantially parallel to the horizontal plane 114 between the first surface 128 and the third surface 132. The second surface 130 is oriented at an angle θ. In examples where the second surface 130 slopes downward, the angle θ is an acute angle measured relative to the horizontal plane 114. In examples where the second surface 130 extends parallel to the horizontal plane 114, the angle θ is 0°.

Suitably, the angle θ is smaller than the angle α. For example, the angle θ is between 0° to approximately 3°, between 0° to approximately 2.5°, between 0° to approximately 2°, between 0° to approximately 1.5°, between 0° to approximately 1°, between 0.5° to approximately 3°, between approximately 0.5° to approximately 2.5°, between approximately 0.5° to approximately 2°, between approximately 0.5° to approximately 1.5°, or between approximately 0.5° to approximately 1°, measured relative to the horizontal plane 114. In one suitable embodiment, the angle θ is approximately 0.7°, measured relative to the horizontal plane 114. In other suitable embodiments, the angle θ is any angle that enables the susceptor 100 to function as described herein.

Suitably, the transition from the first surface 128, oriented at the angle α, to the second surface 130, oriented at the angle θ which is 0° or an acute angle that is smaller than the angle α, defines a narrow space between the ledge 106 and the back surface 304 of the wafer 300 as the ledge 106 extends radially inward from the peripheral edge 306 of the wafer 300, relative to a space between the ledge 106 and the back surface 304 that would otherwise result if the ledge 106 continued to extend at the angle α. This facilitates restricting a flow of gas that may leak between the peripheral edge 306 of the wafer 300 and the first surface 128 of the ledge 106, and facilitates minimizing growth of an epitaxial layer on the back surface 304 during deposition. Additionally, in some examples, the angle θ may suitably be an acute angle larger than 0° to maintain the gap between the back surface 304 and the ledge 106 and facilitate preventing back surface defects that may be caused by contact between the back surface 304 and the ledge 106.

The third surface 132 slopes downward from the second surface 130 to the recess floor 126, and the third surface 132 is oriented at a downward angle β. The angle β is an acute angle measured relative to the horizontal plane 114. The angle β is suitably larger than the angle θ. For example, the angle β is between approximately 2° to approximately 15°, between approximately 3° to approximately 15°, between approximately 4° to approximately 15°, between approximately 5° to approximately 15°, between approximately 6° to approximately 15°, between approximately 7° to approximately 15°, between approximately 8° to approximately 15°, between approximately 9° to approximately 15°, between approximately 10° to approximately 15°, between approximately 2° to approximately 14°, between approximately 2° to approximately 13°, between approximately 2° to approximately 12°, between approximately 2° to approximately 11°, between approximately 2° to approximately 10°, or between approximately 3° to approximately 10°, measured relative to the horizontal plane 114. In suitable embodiments, the angle β may be approximately 3°, approximately 5°, or approximately 10°, measured relative to the horizontal plane 114. In one suitable embodiment, the angle β is approximately 3°, measured relative to the horizontal plane 114. In another suitable embodiment, the angle β is approximately 5°, measured relative to the horizontal plane 114. In another suitable embodiment, the angle β is approximately 10°, measured relative to the horizontal plane 114. In other suitable embodiments, the angle β is any angle that enables the susceptor 100 to function as described herein.

The angles described above for the angles α, θ, and β may be implemented for the respective surfaces 128, 130, and 132 in any suitable combination. In various examples, each of the angles α and β are larger than the angle θ, where the angle θ is an acute angle between 0° to approximately 1° or is 0°, measured relative to the horizontal plane 114. In these examples, the angle β may be larger than the angle α, or the angle α may be larger than the angle β. The angle β may suitably be larger than the angle α of the first surface 128, such that the angle α is between the angles θ and β. The steeper angle β, relative to the angle θ, enables a shorter total length of the ledge 106 by hastening a desired spacing between the recess floor 126 and the back surface 304 of the wafer 300.

In one example, the first angle α is between approximately 3° to approximately 4°, the second angle θ is between 0° to approximately 1°, and the third angle β is between approximately 3° to approximately 10°. In another example, the first angle α is between approximately 3° to approximately 4°, the second angle θ is an acute angle between greater than 0° to approximately 1°, and the third angle β is between approximately 3° to approximately 10°. In another example, the first angle α is between approximately 3° to approximately 4°, the second angle θ is 0°, and the third angle β is between approximately 3° to approximately 10°. In another example, the first angle α is between approximately 3° to approximately 4°, the second angle θ is between 0° to approximately 1°, and the third angle β is approximately 3°, approximately 5°, or approximately °. In another example, the first angle α is approximately 3.18°, the second angle θ is approximately °, and the third angle β is approximately 3°, approximately 5°, or approximately 10°. In these examples, the angle β may be larger than the angle α, or the angle α may be larger than the angle β unless the context clearly indicates otherwise. As described above, the angles α, θ, and β are measured relative to the horizontal plane 114.

The radial lengths L₁, L₂, and L₃ of the first surface 128, the second surface 130, and the third surface 132, respectively, are each a suitable length to enable each surface to perform its intended function. For example, the radial length L₁ of the first surface 128 may be selected to enable the first surface 128 to support the portion of the back surface 302 of the wafer 300 proximate the peripheral edge 306 while facilitating minimizing contact between the back surface 304 of the wafer 300 and the ledge 106. The radial length L₂ of the second surface 130 may be selected to extend a suitable distance along the back surface 304 of the wafer to facilitate minimizing growth of an epitaxial layer on the back surface 304 during deposition. The radial length L₃ of the third surface 132 may be selected to extend a suitable distance to minimize a total radial length of the ledge 106.

Suitably, the radial length L₂ of the second surface 130 is longer than each of the radial length L₁ of the first surface 128 and the radial length L₃ of the third surface 132. In some examples, the radial length L₁ of the first surface 128 may be longer than the radial length L₃ of the third surface 132 and shorter than the radial length L₂ of the second surface 130. Alternatively, the radial length L₃ of third surface 132 may be longer than radial length L₁ of the first surface 128 and shorter than the radial length L₂ of the second surface 130.

The radial length L₁ of the first surface 128 may be between about 0.5 millimeters (mm) to about 2 mm, between about 0.5 mm to about 1.5 mm, between about 1 mm to about 1.5 mm. In one suitable embodiment, the radial length L₁ of the first surface 128 is about 1.2 mm. In other suitable embodiments, the radial length L₁ of the first surface 128 is any length that enables the susceptor 100 to function as described herein.

The radial length L₂ of the second surface 130 may be between about 3 mm to about 6 mm, between about 3 mm to about 5.5 mm, between about 3 mm to about 5 mm, between about 3 mm to about 4.5 mm, between about 3.5 mm to about 6 mm, between about 3.5 mm to about 5.5 mm, between about 3.5 mm to about 5 mm, between about 3.5 mm to about 4.5 mm, between about 4 mm to about 6 mm, between about 4 mm to about 5.5 mm, between about 4 mm to about 5 mm, between about 4 mm to about 4.5 mm, or between about 4.5 mm to about 5 mm. In one suitable embodiment, the radial length L₂ of the second surface 130 is about 4.5 mm. In other suitable embodiments, the radial length L₂ of the second surface 130 is any length that enables the susceptor 100 to function as described herein.

The radial length L₃ of the third surface 132 may be between about 0.3 mm to about 1.2 mm. The radial length L₃ may vary depending on the angle β of the third surface 132. For example, where the angle β is 3°, the length L₃ is suitably between about 1 mm to about 1.2 mm, for example, about 1.16 mm. Where the angle β is 5°, the length L₃ is suitably between about 0.6 mm to about 0.8 mm, for example, about 0.7 mm. Where the angle β is 10°, the length L₃ is suitably between about 0.3 mm to about 0.5 mm, for example, about 0.35 mm. In other suitable embodiments, the radial length L₃ of the third surface 132 is any length that enables the susceptor 100 to function as described herein.

The radial lengths L₁, L₂, and L₃ described above may be implemented for the respective surfaces 128, 130, and 132 in any suitable combination. In various examples, the radial length L₂ is longer than each of the radial lengths L₁ and L₃, and the radial length L₁ may be longer or shorter than the radial length L₃. In one example, the radial length L₁ is between about 0.5 mm to about 1.5 mm, the radial length L₂ is between about 4 mm to about 5 mm, and the radial length L₃ is between about 0.3 mm to about 1.2 mm. In another example, the radial length L₁ is between about 0.5 mm to about 1.5 mm, the radial length L₂ is between about 4 mm to about 5 mm, and the radial length L₃ is between about 1 mm to about 1.2 mm, between about 0.6 mm to about 0.8 mm, or between about 0.3 mm to about 0.5 mm. In another example, the radial length L₁ is about 1.2 mm, the radial length L₂ is about 4.5 mm, and the radial length L₃ is about 1.16 mm, about 0.7 mm, or about 0.35 mm.

Suitably, each of the radial lengths L₁, L₂, and L₃ of the first surface 128, the second surface 130, and the third surface 132, respectively, are constant along the entire circumferential extent of the ledge 106, or along a substantial portion of the circumferential extent of the ledge 106. Thus, in examples where the ledge 106 consists of the first surface 128, the second surface 130, and the third surface 132, the total radial length of the ledge 106 is the sum of the radial lengths L₁, L₂, and L₃ and the total radial length of the ledge 106 is constant along the entire circumferential extent, or a substantial portion of the circumferential extent, of the ledge 106. As the ledge 106 transitions between adjacent surfaces having different orientations (e.g., between the first surface 128 and the second surface 130, between the second surface 130 and the third surface 132, or between the third surface 132 and the recess floor 126), the ledge 106 may have a sharp angle at an intersection of the adjacent surfaces, or the ledge 106 may have a small radius of curvature between adjacent surfaces to smooth the transition at the intersection of the adjacent surfaces.

The ledge 106 may also include a fourth surface 134 that extends a radial length L₄ between the wall 124 and the first surface 128. The fourth surface 134 may be substantially flat, that is, the fourth surface 134 extends substantially parallel to the horizontal plane 114 for the length L₄. The wall 124 may extend substantially perpendicular to the horizontal plane 114 such that the fourth surface 134 and the wall 124 are orthogonal to each other. The fourth surface 134 is positioned radially outward from the first surface 128 and, consequently, radially outward from the peripheral edge 306 of the wafer 300. As a result, the fourth surface 134 increases a radial distance of the space G between the peripheral edge 306 of the wafer 300 and the wall 124. The ledge 106 may have a sharp angle at an intersection between the adjacent first surface 128 and fourth surface 134 and/or an intersection between the adjacent fourth surface 134 and wall 124, or the ledge 106 may have a small radius of curvature between the adjacent first surface 128 and fourth surface 134 and/or the adjacent fourth surface 134 and wall 124 to smooth the transition at the intersection of the adjacent surfaces.

The extent of the space G between the peripheral edge 306 of the wafer 300 and the wall 124 may affect a flatness of the epitaxial layer that is grown on the front surface 302 of the semiconductor wafer 300. For example, if the space G between the peripheral edge 306 of the wafer 300 and the wall 124 is too large, a greater amount of material may be deposited at the peripheral edge 306 and/or on the front surface 302 proximate the peripheral edge 306, which may undesirably increase DERO of the wafer. The radial length L₄ of the fourth surface 134 is selected to facilitate preventing the space G between the peripheral edge 306 and the wall 124 from negatively impacting the flatness of the epitaxial wafer. For example, the radial length L₄ may be between 0 mm to about 2 mm, such as between 0 mm to about 1.1 mm. The radial length L₄ of the fourth surface 134 may be implemented with any of the radial lengths L₁, L₂, and L₃ described for the respective surfaces 128, 130, and 132 in any suitable combination.

The wall 124 defines the general shape of the recess 108. In the example susceptor 100, the wall 124 has a generally annular shape and defines a circular recess 108. In this example, the fourth surface 134, if present, has a constant radial length L₄ along the circumferential extent of the ledge 106. Alternatively, the wall 124 may have a non-annular shape such that the total radial length of the ledge 106 changes along the circumferential extent of the ledge 106, which may require that the radial length L₄ of the fourth surface 134 varies along the circumferential extent of the ledge 106. That is, where the recess floor 126 has a constant diameter, and the first surface 128, the second surface 130, and the third surface 132 each have a constant radial length L₁, L₂, and L₃, respectively, along the circumferential extent of the ledge 106, the change in the total radial length of the ledge 106 along the circumferential extent of the ledge 106 is effected by a change in the radial length L₄ of the fourth surface 134. For example, the radial length L₄ of the fourth surface 134 may vary along the circumferential extent of the ledge 106 between 0 mm and 2 mm, such as between 0 mm and 1.1 mm.

In examples where the susceptor includes a non-annular recess wall 124, the recess 108 has a non-circular shape and a radius of the recess 108 changes as the wall 124 extends circumferentially along the outer rim 104. As such, the recess 108 may be asymmetrical about at least one of the X axis and the Y axis (shown in FIG. 1). For example, the recess 108 may be asymmetrical about the X axis and symmetrical about the Y axis. In other examples, the recess 108 may be symmetrical about the X axis and asymmetrical about the Y axis. In other examples, the recess 108 may be asymmetrical about each of the X axis and the Y axis.

In some examples, the front surface 110 may be substantially flat such that a height of the wall 124, measured as the extent of the wall 124 between the ledge 106 and the front surface 110 of the outer rim 104, is substantially constant along the circumferential extent of the wall 124. In these examples, the front surface 110 of the outer rim 104 is substantially coplanar with the horizontal plane 114 along the circumferential extent of the outer rim 104, and the height of the front surface 110, measured as a distance between the front surface 110 and the central plane 138, is substantially constant along the circumferential extent of the outer rim 104.

Alternatively, the front surface 110 of the outer rim 104 may have a “wavy” shape. The wavy shape of the front surface 110 may complement a non-circular shape of the recess 108, or may be implemented with a circular-shaped recess 108. To provide a wavy shape of the front surface 110 of the outer rim 104, the height of the wall 124 may vary along the circumferential extent of the wall 124. In examples that include a wavy shape of the front surface 110, the height of the front surface 110 varies along the circumferential extent of the outer rim 104. The rear surface 120 may be substantially flat, such that the height of the entire rear surface 120, measured as a distance between the rear surface 120 and the central plane 138, in constant. In examples where the front surface 110 and/or the rear surface 120 is substantially flat, minor variations in the height of the front surface 110 and/or the rear surface 120 may exist due, for example, to manufacturing tolerances.

As shown in FIG. 4, the ledge 106 has a height or a thickness T (hereinafter referred to as a thickness T) at the contact interface 136 between the ledge 106 and the back surface 304 of the wafer 300. In the example susceptor 100, with additional reference to FIG. 5, the thickness T is defined as the distance between the central plane 138 and the first surface 128 at the contact interface 136. The thickness T may vary along the circumferential extent of the ledge 106. More generally, the distance between a surface (e.g., the first surface 128, the second surface 130, or the third surface 132) of the ledge 106 and the central plane 138, that is, the height or thickness of the ledge 106 at the surface, may vary along the circumferential extent of the ledge 106 at a constant radial distance from the center C of the recess 108 (shown in FIG. 1).

Variations in the height of the ledge 106 along the circumferential extent of the ledge 106 result in variations in the flatness of the ledge 106 along the circumferential extent of the ledge 106. As such, variations in the thickness T are representative of the variations in the flatness of the ledge 106. Moreover, the variations in the flatness of the ledge 106, and accordingly variations in the thickness T, may be due to manufacturing tolerances, and can only be controlled to a certain extent.

During deposition, silicon source gas may leak through small gaps (not shown) along the contact interface 136 between the ledge 106 and the back surface 304. The small gaps may be more pronounced at certain locations along the contact interface 136 due to variations in the thickness T of the ledge 106. A more pronounced gap at a location along the contact interface 136 may translate to more silicon source gas leaking through that location along the contact interface 136. As a result, excessive and/or non-uniform leakage of the silicon source gas through the contact interface 136 may result from variations in the thickness T.

The ledge 106 is designed to facilitate minimizing or eliminating excessive and/or non-uniform epitaxial growth that may otherwise result from the leakage of silicon source gas through the contact interface 136, and thereby facilitate minimizing or eliminating the impact that variations in the thickness T have on DERO variations. More specifically, as described above, the first surface 128 is oriented at the angle α and has the radial length L₁, the second surface 130 is oriented at the angle θ and has the radial length L₂, and the third surface 132 is oriented at the angle β and has the radial length L₃. The angle and the length of each surface 128, 130, and 132 is selected to enable the ledge 106 to function as described herein. The susceptor 100 may include additional features that further facilitate minimizing or eliminating the impact that variations in the thickness T have on DERO variations. For example, the ledge 106 may also include a fourth surface 134 that extends radially outward from the first surface 128, and the radial length L₄ may be selected to facilitate minimizing DERO variations during deposition. Additionally, the susceptor 100 may include a non-circular shaped recess 108 and/or a wavy shaped outer rim 104, as described above, and the shape of the recess 108 and outer rim 104 may complement one another to further facilitate minimizing DERO variations during deposition.

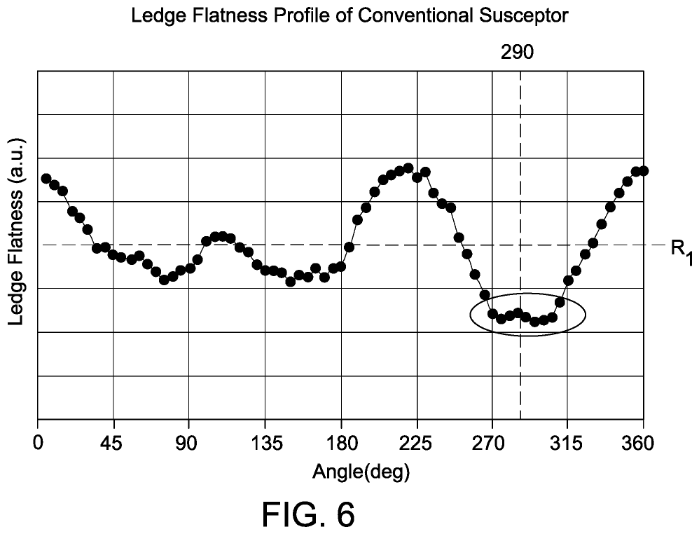

To further illustrate, FIGS. 6-9 compare the effect that variations in the thickness or flatness of a ledge (“ledge flatness”) of a conventional, prior art susceptor have on the DERO of an epitaxial wafer supported by the prior art susceptor and the effect that ledge flatness variations of an example susceptor that includes a ledge having three surfaces, each surface oriented at a different acute angle and extending circumferentially along the ledge, in accordance with the present disclosure, have on the DERO of an epitaxial wafer supported by the example susceptor during an epitaxial deposition process.

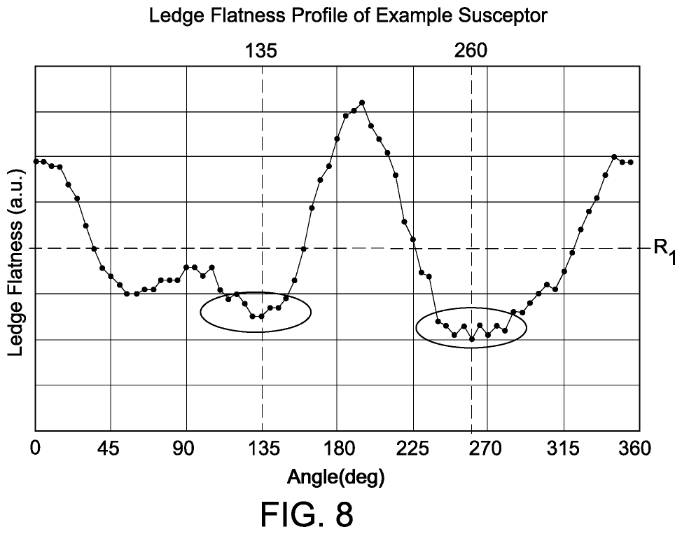

FIG. 6 shows a plot of the ledge flatness profile of the conventional, prior art susceptor that includes a ledge sloped at a single angle. FIG. 8 shows a plot of the ledge flatness profile of the example susceptor. The ledge flatness profile in FIGS. 6 and 8 is characterized by the normalized flatness measured along the circumferential (360 degree) extent of the ledge. In particular, the normalized flatness is measured at various points along the ledge at a constant radius, and the points are each located at a position on the ledge corresponding to a contact interface between the ledge and a wafer supported by the ledge. The normalized flatness is the thickness (or height) of the ledge, measured as the distance between a surface of the ledge and a central plane of the susceptor, at each point normalized to a reference plane R₁. The reference plane R₁ is the least square calculation of all the measured thicknesses of the ledge. Each normalized flatness measurement is quantified in arbitrary units. The ledge flatness profile may vary between susceptors (as is shown in FIGS. 6 and 8), due, for example, to manufacturing tolerances.

As shown in FIG. 6, the prior art susceptor has a ledge flatness “valley” at the 290 degree position. As shown in FIG. 8, the example susceptor has a ledge flatness valley at the 135 degree position and the 270 degree position. The DERO of an epitaxial wafer may be particularly impacted at a position along the near-edge portion of the wafer adjacent the ledge flatness valley position of the susceptor ledge that supports the wafer during deposition.

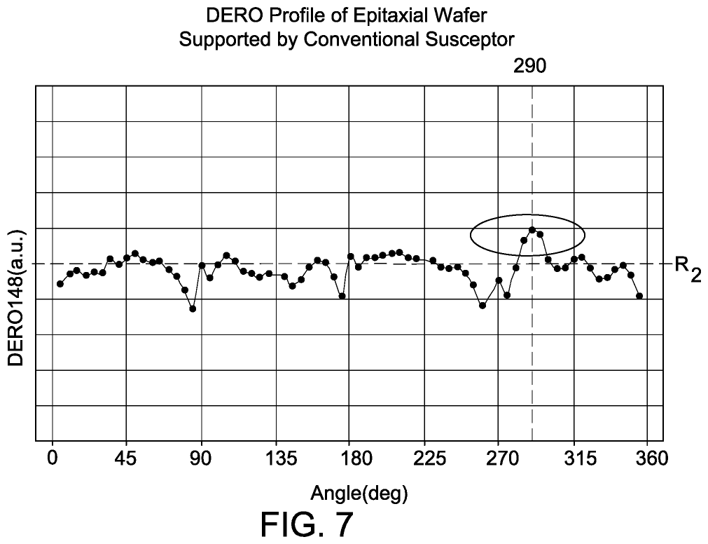

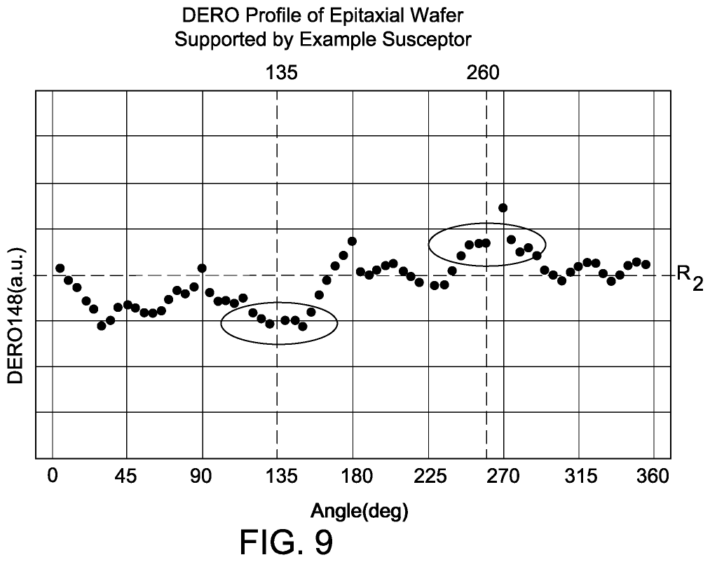

FIG. 7 shows the DERO profile for an epitaxial wafer supported by the prior art susceptor having the ledge flatness profile of FIG. 6. FIG. 9 shows the DERO profile of an epitaxial wafer supported by the example susceptor having the ledge flatness profile of FIG. 8. The DERO profile in FIGS. 7 and 9 is characterized by the normalized DERO measured along the circumferential (360 degree) extent of the near-edge portion of the wafer. In particular, the normalized DERO is measured at various points along the wafer at a constant radius, and the points are each located at a position on the wafer corresponding to the contact interface between the wafer and the susceptor supporting the wafer. The normalized DERO is quantified in arbitrary units and plotted against a reference plane R₂.

As shown in FIG. 7, the epitaxial wafer supported by the prior art susceptor had abnormal DERO at the 290 degree position, which corresponds to the position on the prior art susceptor where a ledge flatness valley was observed. As shown in FIG. 9, the epitaxial wafer supported by the example susceptor did not have abnormal DERO at the 135 degree position and the 260 degree position, which correspond to the positions on the example susceptor where a ledge flatness valley was observed. Thus, the significant ledge flatness variations, characterized by the ledge flatness valley position, in the prior art susceptor resulted in abnormal DERO variations in the epitaxial wafer supported by the prior art susceptor, while the significant ledge flatness variations in the example susceptor did not result in abnormal DERO variations in the epitaxial wafer supported by the example susceptor. Accordingly, the ledge design of the example susceptor facilitates better control of DERO variations in an epitaxial wafer by minimizing the impact of ledge flatness variations in the susceptor.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements. Moreover, the use of “top” and “bottom”, “front” and “rear”, “above” and “below,” “vertical” and “horizontal,” and variations of these and other terms of orientation is made for convenience, and does not require any particular orientation of the components.

The terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

As various changes could be made in the above constructions and methods without departing from the scope of the invention, it is intended that all matter contained in the above description and shown in the accompanying drawings shall be interpreted as illustrative and not in a limiting sense.

What is claimed is:

1. A susceptor supporting a semiconductor wafer in a heated chamber, the semiconductor wafer comprising a forward surface, a back surface, and a peripheral edge joining the forward and back surfaces, the susceptor comprising:
a body having a front surface, a rear surface opposite the front surface, and a central plane extending between the front surface and the rear surface;
a recess extending into the body from the front surface to a recess floor, the recess receiving the semiconductor wafer therein; and
a ledge circumscribing an outer periphery of the recess floor in the recess, the ledge supporting the back surface of the semiconductor wafer proximate the peripheral edge, the ledge comprising:
a first surface oriented at a first acute angle relative to a horizontal plane extending parallel to the central plane;
a second surface extending radially inward from the first surface, the second surface optionally oriented at a second acute angle relative to the horizontal plane; and
a third surface extending between the second surface and the recess floor, the third surface oriented at a third acute angle relative to the horizontal plane;
wherein each of the first, second, and third surfaces extends circumferentially along the ledge.

2. The susceptor according to claim 1, wherein the first surface has a first length and the second surface has a second length that is longer than the first length.

3. The susceptor according to claim 2, wherein the third surface has a third length that is shorter than the second length.

4. The susceptor according to claim 3, wherein the first and second lengths are each longer than the third length.

5. The susceptor according to claim 1, comprising a recess wall extending between the front surface and the ledge, wherein the ledge comprises a fourth surface extending between the recess wall and the first surface and parallel to the horizontal plane.

6. The susceptor according to claim 1, wherein the second surface is oriented at the second acute angle, and wherein the first and third angles are each larger than the second angle.

7. The susceptor according to claim 6, wherein the third angle is larger than the first angle.

8. The susceptor according to claim 6, wherein the second angle is between 0° to 3°.

9. The susceptor according to claim 1, wherein the third angle is between 3° to 10°.

10. The susceptor according to claim 1, wherein the third angle is 10°.

11. The susceptor according to claim 10, wherein a length of the third surface is between 0.3 mm to 0.5 mm.

12. The susceptor according to claim 1, wherein the second surface is oriented at the second angle, and wherein the first angle is between 3° to 4°, the second angle is between 0° to 1°, and the third angle is between 3° to 10°.

13. The susceptor according to claim 12, wherein a first length of the first surface is between 0.5 mm to 2 mm, a second length of the second surface is between 3 mm to 6 mm, and a third length of the third surface is between 0.3 mm to 1.2 mm.

14. A susceptor for supporting a semiconductor wafer in a heated chamber, the susceptor comprising:
a body having a front surface, a rear surface opposite the front surface, and a central plane extending between the front surface and the rear surface;
a wall extending from the front surface and defining a recess in the body, the recess being sized and shaped for receiving the semiconductor wafer therein; and
a ledge extending between the wall and a recess floor, the ledge comprising:
a first surface oriented at a first acute angle relative to a horizontal plane extending parallel to the central plane;
a second surface oriented at a second angle relative to the horizontal plane that is smaller than the first angle; and
a third surface oriented at a third acute angle relative to the horizontal plane;
wherein each of the first, second, and third surfaces extends circumferentially along the ledge, wherein the second surface is positioned between the first surface and the third surface.

15. The susceptor according to claim 14, wherein the ledge comprises a fourth surface extending between the wall and the first surface and parallel to the horizontal plane.

16. The susceptor according to claim 14, wherein the first surface has a first length, the second surface has a second length, and the third surface has a third length, wherein the second length is longer than each of the first and third lengths.

17. The susceptor according to claim 14, wherein the third angle is 10° and a length of the third surface is between 0.3 mm to 0.5 mm.

18. An epitaxial deposition reactor for growing a thin layer of material on a semiconductor wafer, the reactor comprising:
a reaction chamber; and
a susceptor to support the semiconductor wafer within the reaction chamber, the susceptor comprising:
a body having a front surface, a rear surface opposite the front surface, and a central plane extending between the front surface and the rear surface;
a recess extending into the body from the front surface to a recess floor, the recess being sized and shaped for receiving the semiconductor wafer therein; and
a ledge circumscribing an outer periphery of the recess floor in the recess, the ledge comprising:
a first surface oriented at a first acute angle relative to a horizontal plane extending parallel to the central plane;
a second surface extending radially inward from the first surface, the second surface optionally oriented at a second acute angle relative to the horizontal plane; and
a third surface extending between the second surface and the recess floor, the third surface oriented at a third acute angle relative to the horizontal plane;
wherein each of the first, second, and third surfaces extends circumferentially along the ledge.

19. The reactor according to claim 18, wherein the second surface is oriented at the second angle, the second angle being smaller than each of the first angle and the third angle, and wherein a first length of the first surface and a third length of the third surface are each shorter than a second length of the second surface.

20. The reactor according to claim 18, wherein the susceptor comprises a recess wall extending between the front surface and the ledge, wherein the ledge comprises a fourth surface extending between the recess wall and the first surface and parallel to the horizontal plane.
